(19) United States
(12) Patent Application Publication
(10) Pub. No.: US 2025/0003110 A1
(43) Pub. Date: Jan. 2, 2025

(54) CRUCIBLE, CRYSTAL PRODUCTION METHOD, AND SINGLE CRYSTAL

(71) Applicant: TDK Corporation, Tokyo (JP)

(72) Inventors: Katsumi KAWASAKI, Tokyo (JP); Jun Arima, Tokyo (JP); Minoru Fujita, Tokyo (JP); Jun Hirabayashi, Tokyo (JP)

(73) Assignee: TDK Corporation, Tokyo (JP)

(21) Appl. No.: 18/886,067

(22) Filed: Sep. 16, 2024

Related U.S. Application Data
(63) Continuation of application No. PCT/JP2023/000856, filed on Jan. 13, 2023.

(30) Foreign Application Priority Data
Mar. 25, 2022 (JP) 2022-049951

(51) Int. Cl. C30B 15/10; C30B 15/02; C30B 29/16

(52) U.S. Cl. CPC C30B 15/10; C30B 15/02; C30B 29/16

(57) ABSTRACT

A crucible for growing an oxide single crystal comprises a body that includes an oxide containing an additive. In the oxide of the body, a plurality of regions arranged along one axis is set and, among the regions, a concentration of the additive in a first region is higher than a concentration of the additive in a second region. A crystal manufacturing method grows an oxide single crystal by moving a position of an exposed surface of a melt in a crucible along a vertical direction while keeping a seed crystal in contact with the exposed surface. In a gallium oxide single crystal, a concentration of an additive along a growth axis may be within the range of ±5% of an average concentration of the additive.

### CROSS-REFERENCE TO RELATED APPLICATIONS

This application is a continuation application of PCT Application No. PCT/JP2023/000856, filed on Jan. 13, 2023, which claims the benefit of priority from Japanese Patent Application No. 2022-049951, filed on Mar. 25, 2022. The entire contents of the above listed PCT and priority applications are incorporated herein by reference.

### BACKGROUND

### Field

The present disclosure relates to a crucible, a crystal manufacturing method, and a single crystal.

### Description of the Related Art

U.S. Pat. No. 6,997,986 discloses a crucible made of metals such as platinum (Pt) or iridium (Ir). The crucible is used in the Czochralski (CZ) method. In the CZ method, a seed crystal fixed to the tip of a rod is brought into contact with a melt and then slowly pulled while rotating to grow a single crystal.

U.S. Pat. No. 11,028,501 discloses a method for growing a gallium oxide (β-Ga₂O₃) single crystal from a melt contained in an iridium crucible.

Japanese Patent No. 6390568 discloses a crucible made of gallium oxide. This crucible is used for growing a gallium oxide single crystal.

### SUMMARY

The inventors of the present application have conducted intensive studies and discovered that the concentration of additives in an oxide single crystal can become uneven. There is a need for a crucible, a crystal manufacturing method, and a single crystal that can achieve high uniformity in the concentration of additives in single crystals.

The crucible of the present disclosure is for growing an oxide single crystal. The crucible comprises a body that includes an oxide containing an additive. In the oxide of the body, a plurality of regions arranged along one axis is set and, among the regions, a concentration of the additive in the first region is higher than a concentration of the additive in the second region.

The crucible of the present disclosure is for growing a gallium oxide single crystal. The crucible includes a body that includes gallium oxide containing an additive. In the gallium oxide of the body, a plurality of regions arranged along one axis is set and, among the regions, a concentration of the additive in the first region is higher than a concentration of the additive in the second region.

The crucible of the present disclosure is for growing an oxide single crystal and includes a plurality of oxide plates laminated and joined along a thickness direction, wherein a concentration of the additive in each of the oxide plates is different from each other.

The crystal manufacturing method of the present disclosure includes a step of growing the oxide single crystal using the above crucible. This is achieved by moving a position of an exposed surface of the melt in the crucible along a vertical direction while keeping a seed crystal in contact with the exposed surface.

The single crystal of the present disclosure is manufactured by the above crystal manufacturing method. The single crystal described in the present disclosure is an ingot of gallium oxide with Sn or Si added as the additive. The concentration of the additive along the growth axis is within the range of ±5% of the average concentration of the additive.

### BRIEF DESCRIPTION OF THE DRAWINGS

FIG. 1 is a perspective view of the crucible.

FIG. 2 is an exploded perspective view of the crucible.

FIG. 3 is a graph showing the relationship between position Z and additive concentration C in the crucible.

FIG. 4 is a diagram showing the crystal manufacturing apparatus.

FIG. 5 is a diagram showing the structure around the crucible.

FIG. 6A, FIG. 6B, FIG. 6C, FIG. 6D, FIG. 6E, and FIG. 6F are diagrams for explaining the crystal manufacturing method.

FIG. 7 is a graph showing the relationship between position Z and the concentration C(Sn) of Sn in the crucible.

FIG. 8 is a perspective view of an ingot of a single crystal.

FIG. 9 is a graph showing the relationship between position Z and the concentration C(Sn) of Sn in the single crystal.

FIG. 10 is a graph showing the relationship between position Z and the concentration C(Si) of Si in the crucible.

FIG. 11 is a graph showing the relationship between position Z and the concentration C(Si) of Si in the single crystal.

FIG. 12 is a graph showing the relationship between position Z and additive concentration C in the crucible.

FIG. 13 is a graph showing the relationship between position Z and additive concentration C in the crucible.

FIG. 14 is a graph showing the relationship between solidification ratio g and C_{g}/C₀.

### DETAILED DESCRIPTION

Hereinafter, various exemplary embodiments will be described in detail with reference to the drawings. In the drawings, the same or equivalent parts are denoted by the same reference numerals, and redundant descriptions are omitted.

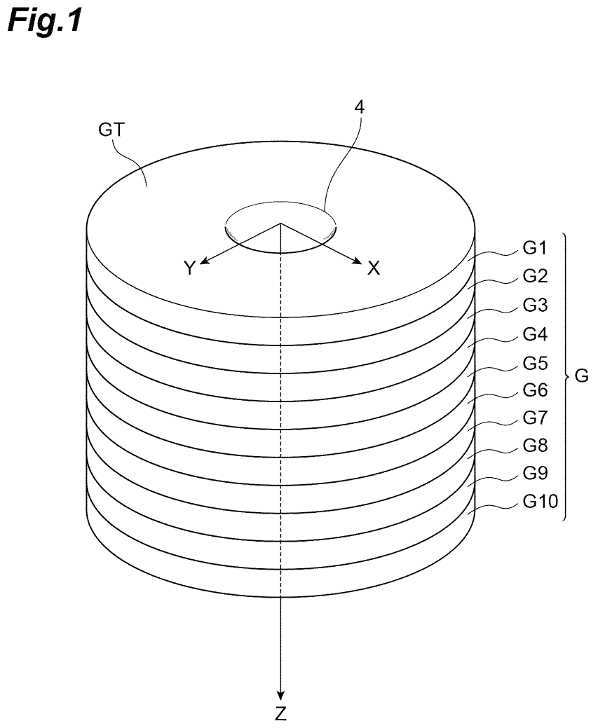

FIG. 1 is a perspective view of the crucible G. The crucible G is used for growing an oxide single crystal. A recess 4 is formed in the central part of the top surface GT of the crucible G. During the crystal growth period, the melt is held in the recess 4, and the seed crystal contacts the exposed surface of the melt. The crucible G comprises a plurality of oxide plates G1 to G10 laminated and joined along the thickness direction, forming a body made of oxide. The body has a cylindrical shape. The number of oxide plates used in the crucible G is two or more. This figure illustrates an example of ten plates.

The stacking direction (thickness direction) of the oxide plates G1 to G10 is defined as the Z-axis. The X-axis is defined as an axis perpendicular to the Z-axis. The Y-axis is defined as an axis perpendicular to both the X-axis and the Z-axis. The figure shows an XYZ three-dimensional orthogonal coordinate system. The top surface GT of the crucible G is parallel to the XY plane. In the XY plane including the top surface GT of the crucible G, the center position of the recess 4 as viewed from the Z-axis direction is set as the origin (0,0,0) of the XYZ three-dimensional orthogonal coordinate system. The positive direction of the Z-axis is set to extend downward from this origin.

The crucible G also serves as the raw material for the single crystal to be manufactured. When the solid material constituting the inner surface of the recess 4 melts, it changes into a liquid phase melt. The melt is used as the raw material for the single crystal to be grown.

The concentration of the additive in each of the oxide plates G1, G2, G3, G4, G5, G6, G7, G8, G9, and G10 is different. In other words, the concentration of the additive varies depending on the part of the crucible G. The concentrations of additives in the oxide plates G1 to G10 are denoted as C(G1) to C(G10), respectively. As an example, these concentrations satisfy the relationship C(G1)>C(G2)>C(G3)>C(G4)>C(G5)>C(G6)>C(G7)>C(G8)>C(G9)>C(G10). In crystal growth, the high degree of freedom in design makes it possible to control the distribution of the additive concentration in the single crystal of the finally grown ingot because the concentration of the additive in each oxide plate G1 to G10 can be independently controlled.

The material of each oxide plate G1 to G10 in this example is a metal oxide (e.g., gallium oxide (Ga₂O₃)), and the additive to the metal oxide is an oxide (e.g., SnO₂ or SiO₂) of an element other than the metal constituting the metal oxide. Note that even with materials other than these, the distribution of additive concentration in the finally grown ingot (single crystal) can be controlled by laminating the plurality of oxide plates.

From this perspective, materials for the oxide plates G1 to G10 can include at least one material selected from the group consisting of aluminum oxide (Al₂O₃), yttrium oxide (Y₂O₃), zirconia (ZrO₂), and lithium niobate (LiNbO₃), other than gallium oxide. As materials for the additives in the oxide plates G1 to G10, at least one selected from the group consisting of SnO₂ and SiO₂ can be used. Other additive such as TiO₂ can also be considered.

Ga₂O₃ has a crystal structure such as α, β, γ, δ, ϵ, or κ. Among these crystal structures, β-Ga₂O₃ has a crystal structure with a monoclinic β-phase and an energy band gap of about 4.8 eV. The melting point of β-Ga₂O₃ is about 1800° C. In this embodiment, β-Ga₂O₃ is presented as a suitable example of gallium oxide.

The additive (e.g., Sn) in the ingot is a specific element (e.g., Sn) contained in the additive (e.g., SnO₂) in the oxide plate. This specific element (e.g., Sn) itself is also an additive in the oxide plate. Therefore, the relationship among the concentrations of the specific element (e.g., Sn) in the plurality of oxide plates is the same as the relationship among the concentrations of the additive (SnO₂) described above. Focusing on the relative relationship of the additive concentration in each oxide plate, the concentration of the additive may be expressed as molar concentration, mass percent concentration, or atomic percent concentration. Unless otherwise specified, the concentration of the additive indicates the mass percent concentration.

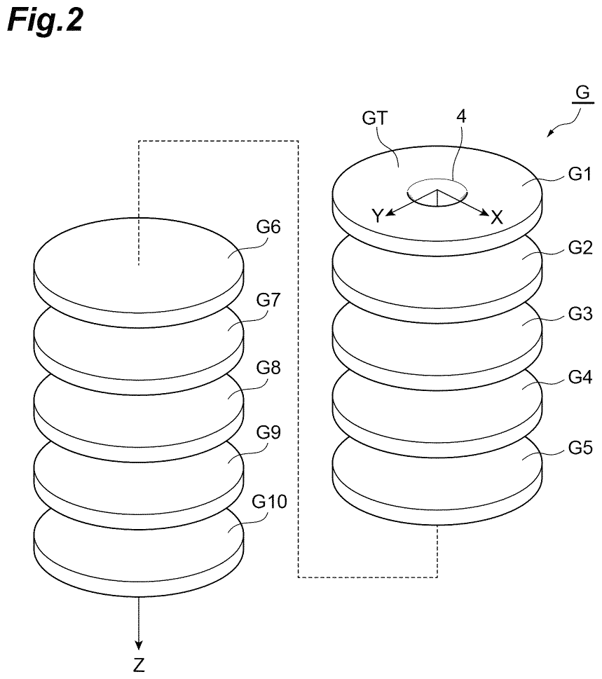

FIG. 2 is an exploded perspective view of the crucible G. The crucible G is formed by laminating the oxide plates G1 to G10 and then joining them by sintering at high temperatures. The figure shows the oxide plates G1 to G10 before sintering.

The manufacturing method of the crucible G is as follows. For example, gallium oxide (Ga₂O₃) can be used as the primary raw material S1, and SnO2 can serve as the additive S2. First, powders of the main raw material S1 and the additive S2 are prepared. Next, after adding the powder of the additive S2 to the powder of the main raw material S1, they are mixed using a mixing method such as a ball mill to obtain a mixed powder. The mixed powder is filled into a rubber mold, shaped into a thin disk, and then compacted using a method such as cold isostatic pressing (CIP). This forms the oxide plates G1 to G10 (disk-shaped compacts). The mixing ratio of the additive S2 varies for each oxide plate G1 to G10. Each oxide plate G1 to G10 is a polycrystalline body of gallium oxide formed by compressing the powder of gallium oxide. The pressure during compaction is about 1000 kg/cm² (98 MPa) and each oxide plate from G1 to G10 may be sintered at about 1300° C. The thickness of each oxide plate from G1 to G10 may be identical or different. In this embodiment, the thickness of each oxide plate from G1 to G10 is identical.

Next, the oxide plates G1 to G10 with different additive concentrations are stacked in the order of the degree of the additive concentration. They are then heated by a heating device to a temperature at which the mixed powder undergoes a sintering reaction, thereby joining and integrating the oxide plates G1 to G10. An electric furnace or other means can be used as the heating device. An exemplary sintering temperature is 1700° C. To control the additive concentration, the sintering temperature is set lower than the melting point (1800° C.) of the main raw material S1.

The recess 4 of the crucible G can be formed by heating the central part of the top surface with infrared rays or the like after placing the crucible G in the crystal manufacturing apparatus. The recess 4 of the crucible G can also be formed by mechanically processing the central part of the top surface. The recess 4 of the crucible G can also be formed by mechanically processing the upper surface of the first oxide plate G1 before sintering. Once the recess 4 is formed, the crucible G can hold the melt in the recess 4.

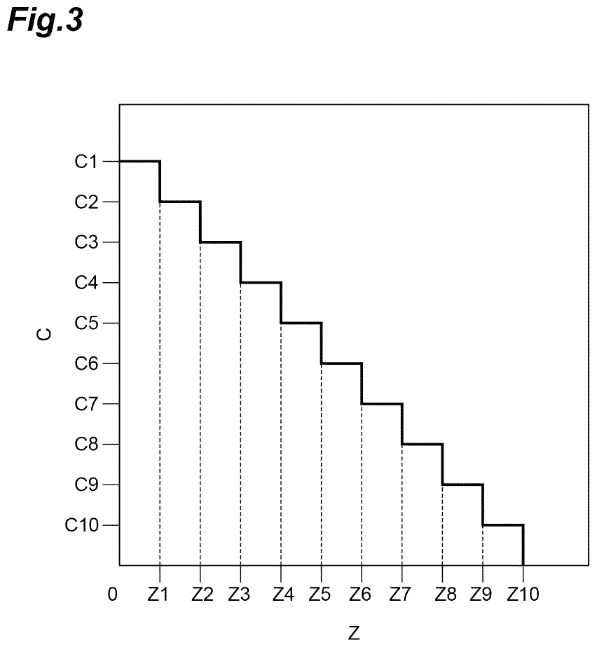

FIG. 3 is a graph showing the relationship between position Z and additive concentration C in the crucible G. The additive concentration C decreases stepwise as its position is further away from the top surface GT of the crucible G (position in the Z-axis direction: Z=0 (denoted as Z0)). In the state before the recess 4 is formed, the additive concentration in the first region from the top surface GT to the first position Z1 is the first concentration C1. The additive concentration in the second region from the first position Z1 to the second position Z2 is the second concentration C2. Similarly, taking (N) as a natural number, the additive concentration in the region from position Z(N−1) to position Z(N) is the concentration C(N).

When (N) regions corresponding to the individual oxide plates are established along the Z-axis direction of crucible G, with Z(N−1) representing the upper end position and Z(N) representing the lower end position of each region, the additive concentration C(N) in each region satisfies the condition C(N−1)>C(N) for any integer N that is 2 or greater.

According to the crucible G of this embodiment, the following effects can be obtained. The crucible G is gradually melted during crystal manufacturing, and the melting location is continuously moved. Since the additive concentration varies depending on the part of the crucible G, the amount of additive dissolved in the melt also changes. The distribution of additive concentration in the crucible G can be freely selected. This is based on the shape of the laminate and the mixing ratio of the additive during the production of the crucible G. By controlling the amount of additives, it is possible to counteract the uneven distribution in the ingot (single crystal) caused by the segregation of additives. This allows for the achievement of a uniform additive concentration in the ingot.

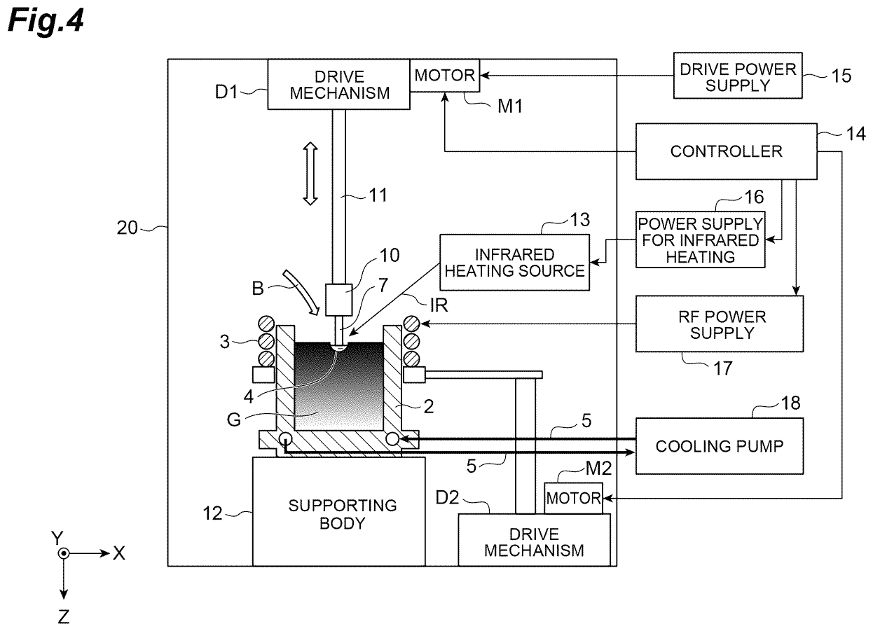

FIG. 4 is a diagram showing the crystal manufacturing apparatus. The crystal manufacturing apparatus includes a supporting body 12 disposed at the lower part of the external frame 20. A crucible stand 2 is placed and supported on the supporting body 12. The crucible G is placed inside the crucible stand 2. The inner surface of the crucible stand 2 is in contact with the outer peripheral surface of the crucible G. A high-frequency coil 3 is arranged around the crucible G. The recess 4 is provided on the top surface of the crucible G, and the lower end of the seed crystal 7 contacts the exposed surface of the melt held in the recess 4. The recess 4 itself or the melt in the recess 4 can be formed by heating with infrared rays IR emitted from the infrared heating source 13.

The seed crystal 7 is held by a seed crystal holder 10, which is fixed to the lower end of a support rod 11. The upper end of the support rod 11 is engaged with a first drive mechanism D1, which can move the support rod 11 up and down along the Z-axis. The first drive mechanism D1 may also be structured to rotate the support rod 11 around the Z-axis. The first drive mechanism D1 is driven by a first motor M1.

The lower end of the high-frequency coil 3 is supported by a support mechanism, and a second drive mechanism D2 engages with this support mechanism, allowing it to move up and down along the Z-axis. The second drive mechanism D2 is driven by a second motor M2.

Each element of the crystal manufacturing apparatus is controlled by a controller 14. The controller 14 is connected to a drive power supply 15 that supplies power to the first motor M1. The controller 14 is connected to the first motor M1 and outputs a rotation control signal to the first motor M1. The controller 14 is connected to the second motor M2 and outputs a rotation control signal to the second motor M2. The controller 14 is connected to an infrared heating power source 16, and the power output from the infrared heating power source 16 is supplied to the infrared heating source 13. The controller 14 is connected to a high-frequency (RF) power supply 17, and the power output from the RF power supply 17 is supplied to the high-frequency coil 3.

The crucible G is installed in the crucible stand 2. The solenoid-type high-frequency coil 3 is arranged around the crucible stand 2. The recess 4 in the center of the top surface of the crucible G can hold the melt 6 in the initial heating stage. To generate the melt 6 in the recess 4 of the crucible G, infrared rays IR from the infrared heating source 13 can be directed into the recess 4. When the magnetic flux density B (magnetic flux) generated from the high-frequency coil 3 passes through the melt and the inner surface of the recess 4, induction heating due to eddy currents occurs, and the crucible material melts.

The crucible stand 2 is a cooling device that functions to cool the outer wall surface of the crucible G. The crucible stand 2 has a flow path through which a cooling medium 5 flows. The cooling medium 5 is circulated by a cooling pump 18. In this example, the cooling medium 5 is water. Various materials can be used as the cooling medium 5. Cooling media such as heavy water, carbon dioxide, helium, metallic sodium, sodium-potassium alloy, mercury, and air are also known.

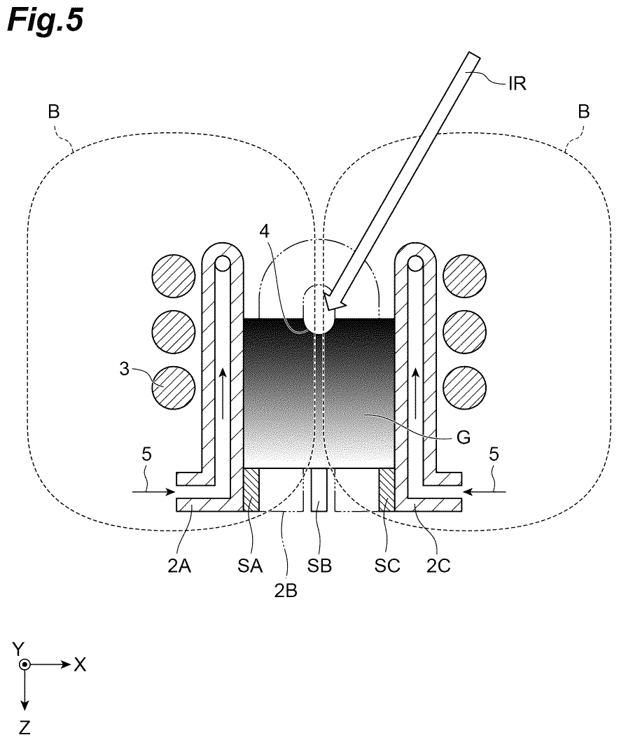

FIG. 5 is a diagram showing the structure around the crucible G. As mentioned above, the crucible G is housed within the crucible stand 2 (see FIG. 4). Various structures can be considered for the crucible stand 2. The exemplary crucible stand shown in the figure includes cooling pipes 2A, 2B, and 2C. Each cooling pipe 2A, 2B, and 2C has a U-shape and is arranged to surround the crucible G. The cooling medium 5 flows inside the cooling pipes 2A, 2B, and 2C. Each U-shaped cooling pipe 2A, 2B, and 2C has a cooling medium inlet at the bottom, extends upward from the cooling medium inlet, makes a U-turn at the top, and extends downward to reach the cooling medium outlet at the bottom. The material of the cooling pipes 2A, 2B, and 2C may be a metal with high thermal conductivity; in this example, it is copper (Cu). The figure shows a cross-sectional view of the structure, displaying three cooling pipes. However, in reality, there are more than three pipes; for example, here there are eight.

The cooling pipes 2A, 2B, and 2C are insulated from each other to prevent the generation of eddy currents induced by the magnetic flux density B (magnetic flux) from the coil. The direction of the magnetic flux density B (magnetic flux) generated by the high-frequency coil 3 is set to be almost perpendicular (e.g., 80 to 100 degrees) to the bottom surface of the deepest part of the recess 4. When the melt is generated, the direction of the magnetic flux density B (magnetic flux) can also be set to be almost perpendicular (e.g., 80 to 100 degrees) to the exposed surface of the melt (the interface with the seed crystal).

The cooling pipes 2A, 2B, and 2C are in close contact with the outer peripheral surface of the crucible G. The bottom surface of the crucible G is supported, for example, by stoppers SA, SB, and SC that contact the bottom surface. The material of the stoppers SA, SB, and SC can be a high-heat-resistant insulator or, if cooling is required, a conductor such as copper, and they can be fixed to the cooling pipes 2A, 2B, and 2C.

In the initial stage of crystal manufacturing, infrared rays (IR) emitted from the infrared heating source 13 (see FIG. 4) are directed onto the inner surface of the recess 4, melting it and generating the melt. If the crucible G is simply a cylindrical oxide body without the recess 4, the initial recess 4 can be formed by irradiating it with infrared rays IR. Once the recess 4 is formed, the crucible G can hold the melt inside it.

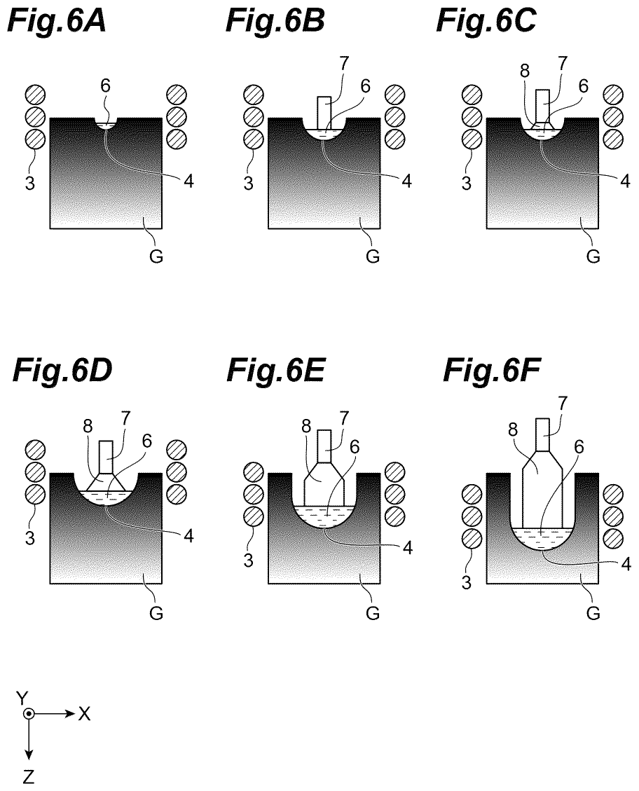

FIG. 6A, FIG. 6B, FIG. 6C, FIG. 6D, FIG. 6E, and FIG. 6F are diagrams for explaining the crystal manufacturing method. The crystal manufacturing apparatus shown in FIG. 4 is used for crystal manufacturing, and unless otherwise specified, the target elements are controlled by instructions from the controller 14.

In the initial heating stage shown in FIG. 6A, the top surface of the crucible G is locally heated using the aforementioned infrared heating source 13 (see FIG. 4) (heating device) or the like to generate the melt 6. The recess 4 may be provided in advance at the center of the top surface of the crucible G to stabilize the holding position of the melt 6. The valence (ionic valence) of the metal element (e.g., Ga) constituting the oxide (e.g., Ga₂O₃) is different from that of the metal element (e.g., Sn) or semiconductor element (e.g., Si) constituting the additive. The mixture constituting the crucible G exhibits conductivity in the molten state. When a high-frequency magnetic field (magnetic flux density B) is applied by the high-frequency coil 3, the conductive melt is inductively heated and generates Joule heat. By increasing the power supplied to the high-frequency coil 3, the melting of the crucible G progresses.

As shown in FIG. 6B, after the melt 6 is generated in the recess 4 on the top surface of the crucible G, the seed crystal 7 is lowered from above, and its lower end is brought into contact with the liquid surface of the melt 6. The power supplied to the high-frequency coil 3 is adjusted so that the melt 6 and the seed crystal 7 coexist, and the temperature is stabilized.

As shown in FIG. 6C, after the temperature is stabilized, the seed crystal 7 is gradually moved upward, causing a crystal 8 to grow as it solidifies at the lower end of the seed crystal 7. The seed crystal 7 can be moved by driving the first drive mechanism D1 shown in FIG. 4 with the first motor M1, and the movement speed and amount can be controlled by control signals output from the controller 14 to the first motor M1.

As shown in FIGS. 6D to 6F, the growth crystal 8 gradually increases in size by the power supplied to the high-frequency coil 3 being adjusted to maintain the amount of melt 6 necessary for crystal growth and gradually moving the high-frequency coil 3 downward. The high-frequency coil 3 can be moved by driving the second drive mechanism D2 shown in FIG. 4 with the second motor M2. The movement speed and amount can be controlled by control signals output from the controller 14 to the second motor M2. As the relative position of the high-frequency coil 3 to the crucible G is gradually moved downward, the position of the melt 6 held in the crucible G also lowers, as shown in these figures.

When the additive concentration in the Z-axis direction within the crucible G varies, the amount of additive supplied from the crucible G to the melt 6 also changes depending on the position of the melt 6. If the amount of additive supplied from the crucible G to the melt 6 is constant, the amount of additive incorporated into the growth crystal 8 (single crystal of the ingot) changes. That is, if the effective segregation coefficient k_{eff} of the additive to the material of the growth crystal 8 (i.e., material of the body of the crucible G) is less than 1, the segregation phenomenon causes the additive concentration to be low in the early stage of growth in the growth crystal 8, and the additive concentration increases as growth progresses. Essentially, if the effective segregation coefficient Kefr is less than 1, only a portion of the additive contained in the melt 6 is incorporated into the growth crystal 8. This leaves the unincorporated additive in the melt 6, causing the additive concentration therein to increase as growth progresses. If the additive concentration in the melt 6 increases, the additive concentration in the growth crystal 8 increases in the later stages of growth.

In contrast, as shown in FIG. 3, if the additive concentration in the crucible G is pre-distributed so that it is higher in the upper portion and lower in the lower portion, the amount of additive supplied from the crucible G decreases as crystal growth progresses. This makes it possible to suppress the segregation of additives.

### Example 1

First, Example 1 will be described. Using the above crystal manufacturing method, an ingot (single crystal) was manufactured. Initially, tin oxide (SnO₂) powder with a purity of 4 N was weighed and added to gallium oxide (Ga₂O₃) powder with a purity of 4 N, and the mixture was blended using a ball mill. After filling the mixed powder into a rubber mold and shaping it into a disk, it was compacted using a cold isostatic pressing (CIP) device to form oxide plates (samples) with a diameter of approximately 100 mm and a thickness of about 10 mm. The pressure during compaction was about 1000 kg/cm2 (98 MPa). The ten oxide plates had varying amounts of tin oxide (SnO₂) added. Each oxide plate was preliminarily sintered at about 1300° C. For the ten oxide plates G1 to G10, the mass ratio of the additive tin oxide (SnO₂) to the mass of the main raw material, gallium oxide (Ga₂O₃), was as follows: G1: 0.71%, G2: 0.66%, G3: 0.60%, G4: 0.54%, G5: 0.48%, G6: 0.42%, G7: 0.34%, G8: 0.27%, G9: 0.18%, and G10: 0.08%.

The stacked oxide plates were heated in an electric furnace at about 1700° C. for 20 hours in an atmosphere of 1 atm, and sintered to integrate them, producing the crucible without a recess in this example. The gallium oxide (Ga₂O₃) constituting the crucible is polycrystalline.

During the single crystal growth period, the pulling speed V_{UP} of the seed crystal was 5 mm/h, the descending speed V_{DOWN} of the high-frequency coil 3 was 2 mm/h, and the rotational speed V_{ROT} of the seed crystal around the Z-axis was 50 rpm. As a suitable example, in this manufacturing method, the high-frequency coil 3 is arranged around the crucible G, which is made of a meltable metal oxide, by induction heating from the high-frequency coil 3. High-frequency power is supplied to the high-frequency coil 3 to melt the recess provided on the top surface of the crucible G. While melting the recess, the seed crystal is brought into contact with the exposed surface of the melt in the recess of the crucible G. The seed crystal is then pulled up at the pulling speed V_{UP} while the high-frequency coil 3 is lowered at the descending speed V_{DOWN} . This process includes the step of growing the oxide single crystal, with the condition that V_{UP}>V_{DOWN}, making it possible to manufacture high-quality oxide single crystals, particularly gallium oxide single crystals.

### Comparative Example 1

In Comparative Example 1, the concentration of tin oxide (SnO₂) in all oxide plates was made the same. For the oxide plates G1 to G10, the mass ratio of the additive tin oxide (SnO₂) to the mass of the main raw material, gallium oxide (Ga₂O₃), was 0.43%. The concentration of tin oxide (SnO₂) in Comparative Example 1 was set to the average value of the concentration of tin oxide (SnO₂) in Example 1. Except for this point, Comparative Example 1 was the same as Example 1, and the crucible without a recess was produced. The gallium oxide that constitutes the crucible is polycrystalline.

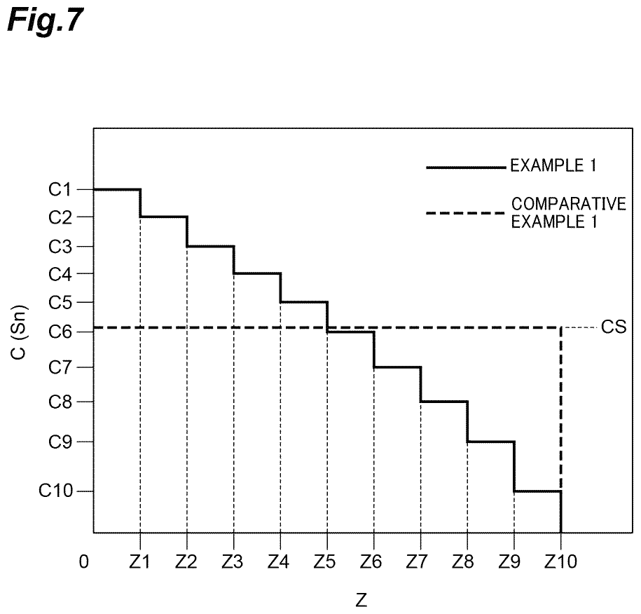

FIG. 7 is a graph showing the relationship between position Z and the concentration C(Sn) of Sn in the crucible G. The figure shows the distribution of the additive concentration in the crucible G before sintering, but the distribution of additives after sintering also has a similar general shape. The concentration distribution of the additive (SnO₂) is the same as the concentration distribution of the specific element (Sn) contained in it. For the N oxide plates (N=10), numbers N=1, 2, 3, . . . , 10 are assigned from the top, and the position of the bottom surface of each oxide plate is ZN. Since the thickness of each oxide plate is 10 mm, Z1=10 mm, and Z(N)−Z(N−1)=10 mm (where N is an integer of 2 or more). In this graph, the concentration C(Sn) is shown in arbitrary units normalized by the average value.

The data values for Example 1 in this graph are as follows.
(Z1, C1)=(10 mm, 1.676)
(Z2, C2)=(20 mm, 1.537)
(Z3, C3)=(30 mm, 1.397)
(Z4, C4)=(40 mm, 1.257)
(Z5, C5)=(50 mm, 1.117)
(Z6, C6)=(60 mm, 0.978)
(Z7, C7)=(70 mm, 0.791)
(Z8, C8)=(80 mm, 0.628)
(Z9, C9)=(90 mm, 0.428)
(Z10, C10)=(100 mm, 0.186)

In Comparative Example 1, the value of the concentration C(Sn) is constant regardless of the position Z, with an average concentration value of CS=1.

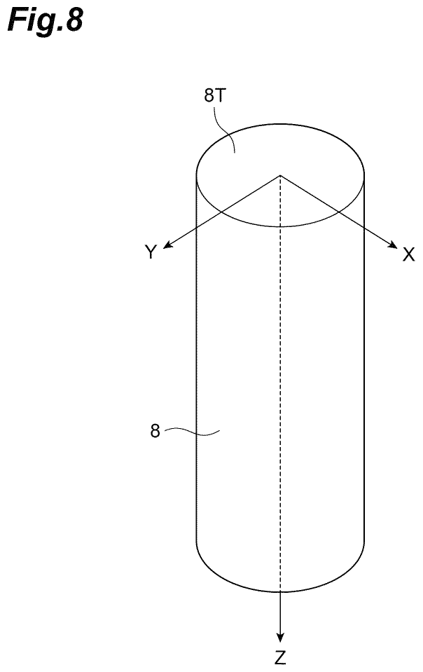

FIG. 8 is a perspective view of an ingot of the grown crystal (single crystal). In the initial state of growth, the position of the initial interface 8T with the seed crystal is Z=0, and as the growth time progresses, the crystal extends along the positive direction of the Z-axis. Although the figure schematically shows the diameter of the ingot as constant along the Z-axis direction, in practice, the upper diameter depends on the diameter of the seed crystal. The manufactured ingot was cut along a plane perpendicular to the Z-axis (XY plane) into 12 equal parts to produce flat plate samples, and the concentration C(Sn) of Sn on the top surface of the flat plate samples was measured. A multi-wire saw can be used for the cutting. The concentration of the additive was measured by emission analysis using Laser Ablation Inductively Coupled Plasma Mass Spectrometry (LA-ICP-MS). For the mixed powder, approximately 1 g of powder sampled before the compaction was measured. For the single crystal, measurements were taken at one central location and four locations near the periphery of the flat plate sample, and the average value was used as the representative value.

### Evaluation of Additive Concentration Distribution

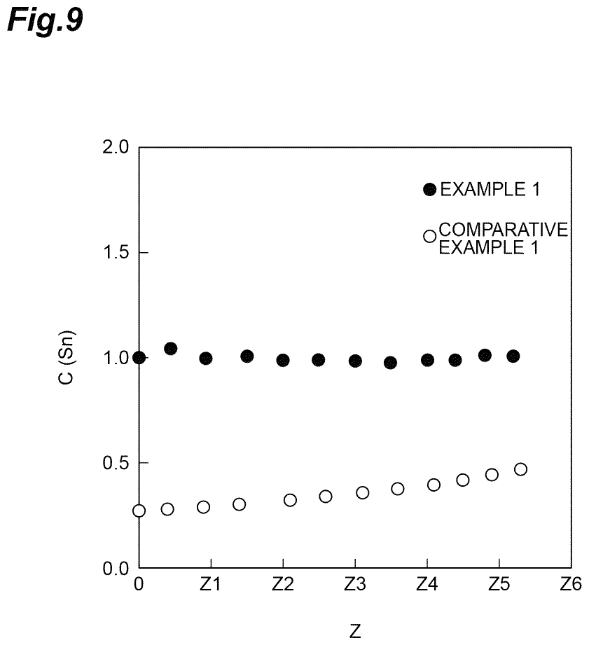

FIG. 9 is a graph showing the relationship between position Z and the concentration C(Sn) of Sn in the grown single crystal. In this graph, the concentration C(Sn) is shown in arbitrary units normalized by the average value. In Example 1, the concentration C(Sn) was almost constant along the Z-axis direction. When the average value was set to 100%, the maximum concentration of the additive was 104%, and the minimum was 97.5%. Even allowing for an error of about 1% from the maximum value of 104%, the concentration of the additive along the growth axis (Z-axis) within the range of the average concentration ±5%, with little variation. In Comparative Example 1, the concentration C(Sn) increased along the positive direction of the Z-axis.

In this graph, the position Z is shown in arbitrary units, assuming the diameter of the ingot is constant. In practice, this position Z indicates the solidification ratio, which is the ratio of the mass of the entire raw material (or the entire crucible) to the mass of the single crystal when growing a single crystal from the melt.

The data for position Z(solidification ratio) and concentration C in Example 1 are as follows: (Z, C)=(0, 1), (0.045, 1.04), (0.093, 0.995), (0.15, 1.005), (0.2, 0.985), (0.25, 0.99), (0.3, 0.98), (0.35, 0.975), (0.4, 0.985), (0.44, 0.99), (0.48, 1.01), (0.52, 1.005).

The data for position Z (solidification ratio) and concentration C in Comparative Example 1 are as follows: (Z, C)=(0, 0.27), (0.04, 0.278), (0.09, 0.289), (0.14, 0.301), (0.21, 0.320), (0.26, 0.336), (0.31, 0.354), (0.36, 0.373), (0.41, 0.396), (0.45, 0.417), (0.49, 0.441), (0.53, 0.468).

### Example 2

Next, Example 2 will be described. In Example 2, instead of the SnO₂ powder used in Example 1, an SiO₂ (silicon dioxide) powder with a purity of 4N was used as the additive. For the ten oxide plates G1 to G10, the mass ratio of the additive (SiO₂) to the mass of the main raw material, gallium oxide, was as follows: G1:0.27%, G2:0.25%, G3:0.23%, G4:0.21%, G5:0.19%, G6:0.17%, G7:0.14%, G8:0.11%, G9:0.08%, and G10:0.03%. Except for this point, Example 2 was the same as Example 1, and the crucible without a recess was produced. The gallium oxide that constitutes the crucible is polycrystalline.

### Comparative Example 2

In Comparative Example 2, the concentration of SiO₂ in all oxide plates was made the same. For the oxide plates G1 to G10, the mass ratio of the additive (SiO₂) to the mass of the main raw material, gallium oxide, was 0.17%. The concentration of SiO₂ in Comparative Example 2 was set to the average value of the concentration of SiO₂ in Example 2. Except for this point, Comparative Example 2 was the same as Example 2, and the crucible without a recess was produced. The concentration distribution of the additive can be measured in the same way as in Example 1 and Comparative Example 1. The gallium oxide that constitutes the crucible is polycrystalline.

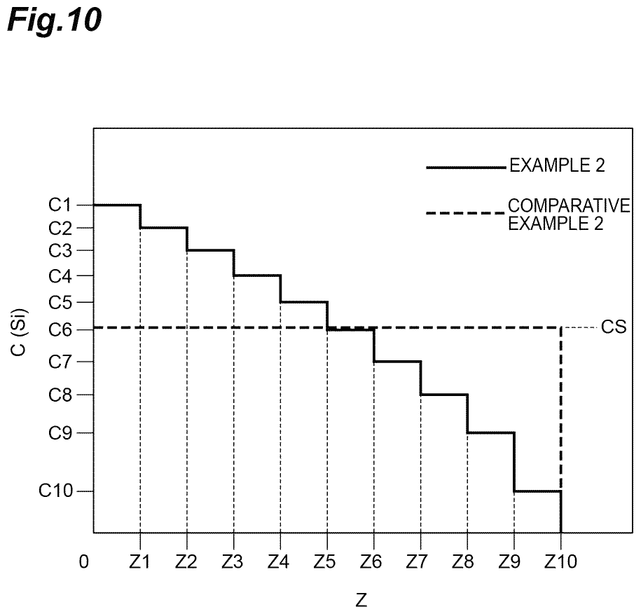

FIG. 10 is a graph showing the relationship between position Z and the concentration C(Si) of Si in the crucible G. The figure shows the distribution of additive concentration in the crucible G before sintering, but the distribution of additives after sintering also has a similar general shape. The concentration distribution of the additive (SiO₂) is the same as the concentration distribution of the specific element (Si) contained in it. For the N oxide plates (N=10), numbers N=1, 2, 3, . . . , 10 are assigned from the top, and the position of the bottom surface of each oxide plate is ZN. Since the thickness of each oxide plate is 10 mm, Z1=10 mm, and Z(N)−Z(N−1)=10 mm (N is an integer of 2 or more). In this graph, the concentration C(Si) is shown in arbitrary units normalized by the average value.

The data values for Example 2 in this graph are as follows:
(Z1, C1)=(10 mm, 1.597)
(Z2, C2)=(20 mm, 1.487)
(Z3, C3)=(30 mm, 1.371)
(Z4, C4)=(40 mm, 1.250)
(Z5, C5)=(50 mm, 1.122)
(Z6, C6)=(60 mm, 0.983)
(Z7, C7)=(70 mm, 0.833)
(Z8, C8)=(80 mm, 0.671)
(Z9, C9)=(90 mm, 0.480)
(Z10, C10)=(100 mm, 0.202)

In Comparative Example 2, the value of the concentration C(Si) is constant regardless of the position Z, with an average concentration value of CS=1.

In Example 2 and Comparative Example 2, as in Example 1 and Comparative Example 1, the manufactured ingot was cut along a plane perpendicular to the Z-axis (XY plane) into 12 equal parts to produce flat plate samples, and the concentration C(Si) of Si on the top surface of the flat plate samples was measured in the same manner as in Example 1.

### Evaluation of Additive Concentration Distribution

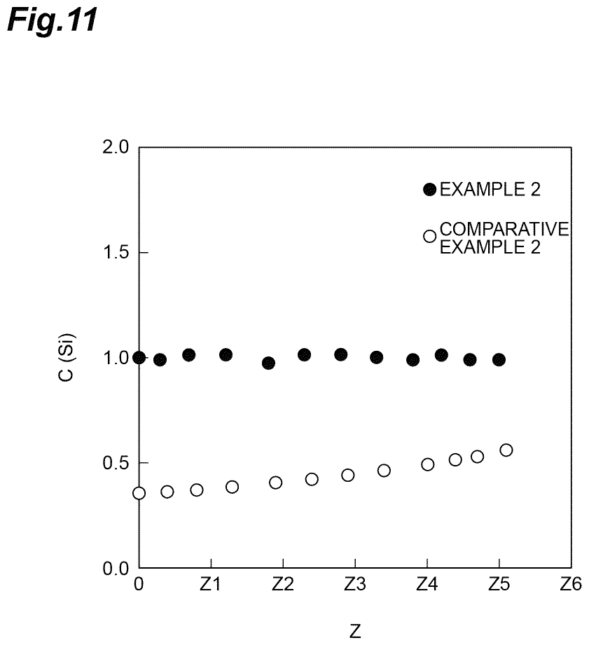

FIG. 11 is a graph showing the relationship between position Z and the concentration C(Si) of Si in the single crystal. In this graph, the concentration C(Si) is shown in arbitrary units normalized by the average value. In Example 2, the concentration C(Si) was almost constant along the Z-axis direction. When the average value was set to 100%, the maximum concentration of the additive was 101%, and the minimum was 97%. Even allowing for an error of about 1% from the minimum value of 97%, the concentration of the additive along the growth axis (Z-axis) was within the range of the average concentration +4%. At least, the concentration of the additive along the growth axis (Z-axis) was within the range of +5% of the average concentration, with suppressed variation. In Comparative Example 2, the concentration C(Si) increased along the positive direction of the Z-axis.

In this graph, the position Z is shown in arbitrary units, assuming the diameter of the ingot is constant. In practice, this position Z indicates the solidification ratio.

The data for position Z(solidification ratio) and concentration C in Example 2 are as follows: (Z, C)=(0, 1), (0.03, 0.985), (0.07, 1.01), (0.12, 1.01), (0.18, 0.97), (0.23, 1.01), (0.28, 1.01), (0.33, 1), (0.38, 0.99), (0.42, 1.01), (0.46, 0.99), (0.5, 0.99).

The data for position Z(solidification ratio) and concentration C in Comparative Example 1 are as follows: (Z, C)=(0, 0.35), (0.04, 0.359), (0.08, 0.369), (0.13, 0.38), (0.19, 0.401), (0.24, 0.418), (0.29, 0.43), (0.34, 0.458), (0.4, 0.487), (0.44, 0.510), (0.47, 0.528), (0.51, 0.556).

As described above, the crucible mentioned above is used for growing an oxide single crystal, comprising a body that includes an oxide containing an additive. In the oxide of the body, the plurality of regions arranged along one axis is set, and among the regions, the concentration of the additive in the first region is higher than the concentration of the additive in the second region. When using this crucible, it is possible to manufacture an oxide single crystal with a uniform additive concentration distribution along one axis (Z-axis) direction.

The structure of the present disclosure can be modified in various ways. Elements disclosed in the embodiments may be omitted, replaced, and/or changed as necessary. For example, the number of oxide plates used in the manufacture of the crucible can be modified to two.

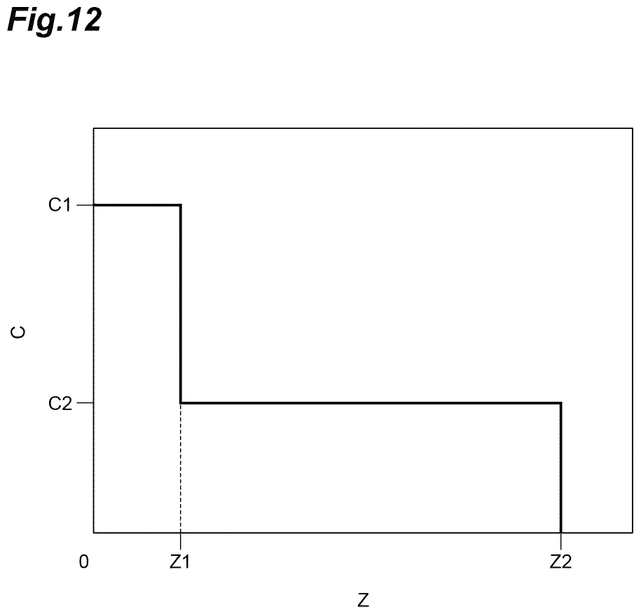

FIG. 12 is a graph showing the relationship between position Z and the concentration of the additive C in the crucible. The crucible has two regions set along the Z-axis direction, with the concentration of the additive in the first region on the surface side set higher. The first concentration C1 of the additive in the first region, from position 0 to the first position Z1, is higher than the second concentration C2 of the additive in the second region from the first position Z1 to the second position Z2. The number of regions set in the crucible can be two or more as described above. In other words, in Examples 1 and 2, the number of regions set in the crucible is three or more, and the concentration of the additive in each of the regions decreases along one axis (=Z-axis) as a position of each of the regions is further away from the first region. The more regions set in the crucible, the more precise the control of the additive concentration distribution can be. Therefore, it is preferable to have three or more regions, and even more preferable to have N or more regions (N=4, 5, 6, 7, 8, 9, 10). The suitable upper limit of this number (N) can be set to, for example, 50 or less in view of manufacturing cost.

When the above crucible is used for growing a gallium oxide single crystal, the crucible comprises a body that includes gallium oxide containing an additive. In the gallium oxide body, the plurality of regions arranged along one axis is set, and among the regions, the concentration of the additive in the first region is higher than the concentration of the additive in the second region. When using this crucible, it is possible to manufacture a gallium oxide single crystal with a uniform additive concentration distribution along one axis (Z-axis). In the above crucible, the additive includes at least one selected from the group consisting of SnO₂ and SiO₂. When these additives are incorporated into the single crystal, the metal element or semiconductor element in the single crystal ingot can function as an N-type impurity.

Regardless of the material of the oxide, to make the additive function as an N-type in the above crucible, the valence (ionization: tetravalent) of the metal element or semiconductor element (e.g., Sn or Si) constituting the additive is set higher than the valence of the metal element (Ga:trivalent) constituting the oxide (e.g., Ga₂O₃) contained in the body of the crucible. In a suitable example, each oxide plate contains gallium oxide in the above crucible, and the additive includes at least one selected from the group consisting of SnO₂ and SiO₂. There are cases where it includes only SnO₂, only SiO₂, or both SnO₂ and SiO₂.

As exemplified in FIGS. 1 to 3, the above crucible is used for growing the oxide single crystal. It comprises the oxide plates (G1 to G10) laminated and joined along the thickness direction (Z-axis direction), with different concentrations of additives in each oxide plate. Free design is possible due to the different concentrations, and single crystals with highly uniform additives can also be obtained.

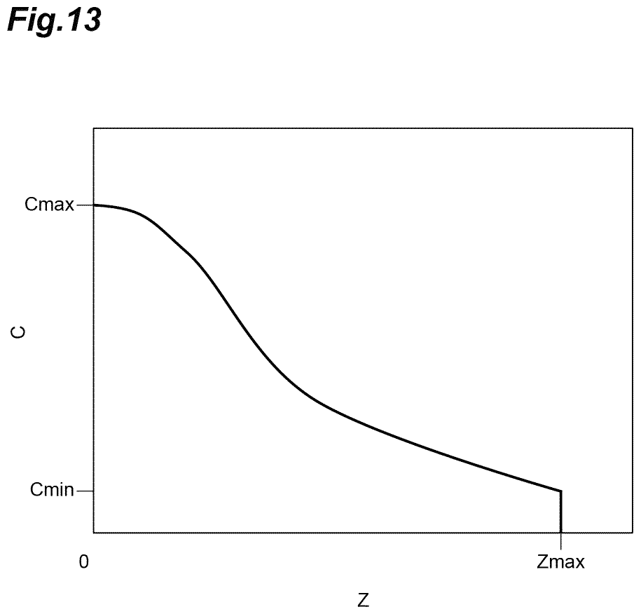

FIG. 13 is a graph showing the relationship between position Z and the concentration of the additive C in the crucible. The crucible has two or more continuous regions set along the Z-axis direction, with the concentration of the additive in the first region on the surface side set higher. The first concentration C1 of the additive in the first region from position 0 to an appropriate position on the surface side is higher than the second concentration C2 of the additive in the second region from this position to a deeper position. The maximum concentration Cₘₐₓ on the top surface of the crucible decreases as the position Z increases. At the position Zₘₐₓ, which is on the bottom surface of the crucible, it reaches the minimum concentration Cmin. Even in such a concentration distribution, the above effects can be achieved.

The crystal manufacturing method includes a step of growing the oxide single crystal using the above crucible. This is achieved by moving the position of the exposed surface of the melt in the crucible along the vertical direction while keeping the seed crystal in contact with the exposed surface. When using the above crucible, it is possible to manufacture single crystals with a uniform additive concentration distribution along the Z-axis.

The grown single crystal is manufactured by the above crystal manufacturing method. The numerical values in the embodiment can achieve the same effect, even with an error of at least ±20%.

This single crystal is the gallium oxide crystal made from an ingot with Sn or Si added as an additive. The concentration of the additive along the growth axis (Z-axis) is within the range of ±5% of the average value of the additive. This average value is the average concentration of the additive distributed throughout the ingot. In the above example, the ingot was cut in a direction perpendicular to the growth axis to form the plurality of flat plate samples. The concentration of the additive was measured at one central location and four locations near the periphery of each flat plate sample. The average value of these five data points was taken as the concentration of the additive in each flat plate sample. The average concentration of the additive in the ingot can be obtained by summing the concentrations of the additive in the N flat plate samples and dividing the total by N.

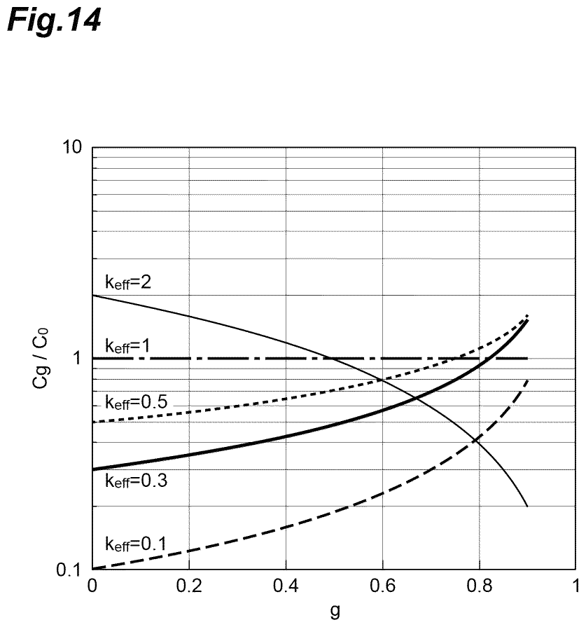

FIG. 14 is a graph showing the relationship between the solidification ratio g and C_{g}/C₀. This graph shows the normalized concentration C_{g}/C₀ when a certain amount of melt is prepared and gradually solidifies. The concentration C_{g} indicates the concentration of the additive in the crystal (ingot solid), and C₀ indicates the initial concentration in the melt. When the solidification ratio g is in the range of 0 to 1, the definite integral of the concentration C_{g} of the additive yields a value of C₀. Note that C_{g}=C₀×k_{eff}×(1−g)^{keff-1}.

In the case where the concentration of the additive in the crucible is constant, as in Comparative Examples 1 and 2, and for example, when the effective segregation coefficient k_{eff}=0.3, the additive is not well incorporated into the grown ingot crystal. As a result, the concentration of the additive in the melt gradually increases with the consumption of the melt (ingot solidification ratio g, position Z in the crucible). Similarly, the concentration of the additive in the solid C_{g} also gradually increases. When a limited amount of melt is prepared in advance, the additive not incorporated into the ingot solid becomes concentrated in the later stage of growth. The segregation shown in the graph can be offset by setting the concentration distribution of the additive in the crucible before sintering to be proportional to the inverse of the segregation distribution of the effective segregation coefficient k_{eff}.

In the above crucible, the first region is located on the side on which the oxide melts in the early stage of single crystal growth if the effective segregation coefficient koff of the additive to the material of the oxide contained in the body is less than 1, as in the case of gallium oxide.

A supplementary explanation of the effective segregation coefficient k_{eff} will be provided here. When the valence or size (ionic radius) of the element constituting the crystal and the element of the additive are different, the ease of incorporation into the crystal during solidification from the melt varies. The ratio of the concentration of the additive in the growing crystal to the concentration of the additive in the melt is called the segregation coefficient k. The segregation coefficient k generally has a value other than 1. The segregation coefficient k in actual dynamic crystal growth is called the effective segregation coefficient k_{eff} because it indicates the value in an equilibrium state. In single crystal growth, since only a portion of the additive is often incorporated, the effective segregation coefficient typically satisfies k_{eff}<1.

When k_{eff}<1, the concentration of the additive in the growing crystal is lower than the concentration of the additive in the melt, and the additive not incorporated into the crystal remains in the melt. As the crystal grows, the additive in the melt becomes concentrated, causing the concentration of the additive in the crystal to gradually increase. The concentration of the additive in the parts precipitated in the early stages of crystallization is low, whereas the concentration of the additive in the parts precipitated in the later stages of crystallization is high, resulting in an uneven concentration distribution.

When 1<k_{eff}, the opposite phenomenon occurs: the concentration of the additive in the parts precipitated in the early stages of crystallization is high, whereas the concentration of the additive in the parts precipitated in the later stages of crystallization is low, resulting in a concentration distribution.

The above crucible is used for manufacturing an oxide single crystal. The crucible is composed of raw materials for an oxide single crystal, holds the oxide melt, and contains additives to be added into the single crystal. By using this crucible, it is possible to control the amount of additive added during crystal growth without the need for a complex additive supply mechanism. In this crucible, the concentration of the additive varies depending on the part of the crucible. When the effective segregation coefficient k_{eff} of the additive to the single crystal is less than 1, the concentration of the additive in the part of the crucible that melts in the early stages of growth is higher than in the part that melts in the later stages of growth. Conversely, when the effective segregation coefficient Kefr exceeds 1, the concentration of the additive in the part of the crucible that melts in the early stages of growth is lower than in the part that melts in the later stages of growth. The crucible and manufacturing method for growing an oxide single crystal according to this embodiment can produce single crystals with suppressed segregation of additives.

The effective segregation coefficient k_{eff} depends on the materials of the ingot (single crystal) and the additive. Since the material of the ingot is the same as the material of the crucible, the effective segregation coefficient k_{eff} depends on the relationship between the material of the crucible and the material of the additive. The crucible is made of oxide. In the above embodiment, the oxide is a metal oxide, specifically Ga₂O₃, and its sintered body is polycrystalline. When the additive is Sn or Si, the effective segregation coefficient k_{eff}<1, for example, is 0.3.

As a combination of oxide and additive materials that satisfy k_{eff}>1, there are, for example, Y₃Al₅O₁₂ and Cr (or Cr₂O₃). In such cases, the distribution of the additive along the Z-axis direction in the crucible is opposite to the above distribution. This crucible comprises a body that includes an oxide containing an additive and, in the oxide of the body, the plurality of regions arranged along one axis is set. The concentration of the additive in the first region is higher than the concentration of the additive in the second region among the regions. However, the second region is located above the first region. In other words, when the effective segregation coefficient k_{eff} of the additive to the oxide material contained in the body is greater than 1, the second region is located on the side on which the oxide melts in the early stages of single crystal growth.

As described above, according to the above crucible and manufacturing method, it is possible to obtain single crystals with highly uniform additive concentration along the growth axis. Particularly, when Ga₂O₃ is used as the metal oxide constituting the ingot, controlling the concentration of additives that influence electrical behavior is important for applications in electronic devices. Some oxides are thermodynamically unstable at high temperatures and, when heated near their melting point in an atmosphere with an oxygen concentration of a few percent or less, they develop oxygen vacancies. Oxygen vacancies inside the crystal can act as color centers in optical materials, causing a decrease in light transmittance, or affecting the activation of dopants in semiconductor materials.

When using the crucible made of iridium, which is a noble metal, it is relatively resistant to oxidation. However, in an atmosphere with an oxygen concentration of around 20%, it oxidizes at temperatures above 1100° C. to form oxides (such as IrO₂). When using an iridium crucible during crystal growth, it is necessary to suppress the oxygen concentration to a few percent or less to prevent the oxidation of iridium. On the other hand, β-Ga₂O₃, which is attracting attention as a wide-gap semiconductor, also develops high-density oxygen vacancies when crystal growth is performed under low oxygen concentration. Oxygen vacancies act as

N-type impurities and generate high concentrations of donors, making precise control of donor concentration difficult. When using the crucible according to the embodiment instead of an iridium crucible, the crucible is made of oxide, so there is no need to suppress oxidation. Additionally, control of additives other than oxygen is desired regardless of the partial pressure of oxygen.

When using additives such as metals or semiconductors like Sn or Si, the above crucible and manufacturing method result in highly uniform additive concentration, which is beneficial. According to the above method, precise control of the additive concentration is possible because the crucible material is an oxide. Since the crucible material and the single crystal material are the same, the contamination of the single crystal with unwanted impurities can also be suppressed.

Oxide single crystals are added with additives to obtain material properties suitable for their intended use. According to the above method, the additive is uniformly distributed within the crystal when dividing the single crystal into multiple parts to form devices, allowing for consistent characteristics between devices. The manufactured single crystal can be applied not only to electrical devices but also to devices utilizing physical properties.

It is to be understood that not all aspects, advantages, and features described herein may necessarily be achieved by, or included in, any one particular example. Indeed, having described and illustrated various examples herein, it should be apparent that other examples may be modified in arrangement and detail.

What is claimed is:

1. A crucible for growing an oxide single crystal, comprising a body that includes an oxide containing an additive,
wherein, in the oxide of the body, a plurality of regions arranged along one axis is set and, among the regions, a concentration of the additive in a first region is higher than a concentration of the additive in a second region.

2. A crucible for growing a gallium oxide single crystal, comprising:
a body that includes a gallium oxide containing an additive,
wherein, in the gallium oxide of the body, a plurality of regions arranged along one axis is set and, among the regions, a concentration of the additive in a first region is higher than a concentration of the additive in a second region.

3. The crucible according to claim 1,
wherein an effective segregation coefficient k_{eff} of the additive to a material of the oxide contained in the body is less than 1, and
the first region is located on a side on which the oxide melts in an early stage of single crystal growth.

4. The crucible according to claim 1,
wherein a number of the regions is three or more, and
the concentration of the additive in each of the regions decreases as a position of each of the regions is further away from the first region along the one axis.

5. The crucible according to claim 1,
wherein a valence of a metal or semiconductor element constituting the additive is greater than the valence of a metal element constituting the oxide contained in the body.

6. The crucible according to claim 2,
wherein the additive includes at least one selected from the group consisting of SnO₂ and SiO₂.

7. A crucible for growing an oxide single crystal, comprising:
a plurality of oxide plates laminated and joined along their thickness direction,
wherein a concentration of an additive in each of the oxide plates is different from each other.

8. The crucible according to claim 7,
wherein each of the oxide plates contains gallium oxide, and
the additive includes at least one selected from the group consisting of SnO₂ and SiO₂.

9. A crystal manufacturing method for growing the oxide single crystal by using the crucible according to claim 1, the method comprising:
moving a position of an exposed surface of a melt in the crucible along a vertical direction while keeping a seed crystal in contact with the exposed surface.

10. A single crystal manufactured by the crystal manufacturing method according to claim 9.

11. A gallium oxide single crystal made from an ingot to which Sn or Si is added as an additive, wherein a concentration of the additive along a growth axis is within a range of ±5% of an average concentration of the additive.

12. The crucible according to claim 2,
wherein an effective segregation coefficient k_{eff} of the additive to a material of the oxide contained in the body is less than 1, and
the first region is located on a side on which the oxide melts at an early stage of single crystal growth.

13. The crucible according to claim 2,
wherein a number of the regions is three or more, and
the concentration of the additive in each of the regions decreases as a position of each of the regions is further away from the first region along the one axis.

14. The crucible according to claim 2,
wherein a valence of a metal or a semiconductor element constituting the additive is greater than the valence of a metal element constituting the oxide contained in the body.

15. A crystal manufacturing method for growing the oxide single crystal by using the crucible according to claim 2, the method comprising:
moving a position of an exposed surface of a melt in the crucible along a vertical direction while keeping a seed crystal in contact with the exposed surface.

16. A crystal manufacturing method for growing the oxide single crystal by using the crucible according to claim 7, the method comprising:
moving a position of an exposed surface of a melt in the crucible along a vertical direction while keeping a seed crystal in contact with the exposed surface.
